(19) United States
(12) Patent Application Publication
(10) Pub. No.: US 2016/0302334 A1
(43) Pub. Date: Oct. 13, 2016

(54) Cable Shielding Assembly and Process of Producing Cable Shielding Assembly

(71) Applicant: Tyco Electronics Corporation, Berwyn, PA (US)

(72) Inventors: Jialing Wang, Mountain View, CA (US); Richard B. Lloyd, Sunnyvale, CA (US); Ting Gao, Palo Alto, CA (US); Jaydip Das, Cupertino, CA (US)

(73) Assignee: Tyco Electronics Corporation, Berwyn, PA (US)

(21) Appl. No.: 14/684,276

(22) Filed: Apr. 10, 2015

(51) Int. Cl. H05K 9/00; H01B 13/22; H01B 3/00; H01B 7/02; H01B 3/30

(52) U.S. Cl. CPC H05K 9/0098; H01B 7/0216; H01B 3/30; H01B 3/004; H01B 13/22

(57) ABSTRACT

Cable shielding assemblies and processes of producing cable shielding assemblies are described. The cable shielding assemblies include a conductor and a conductive composite shield extending around at least a portion of the conductor, the conductive composite shield having a non-conductive matrix and conductive particles within the non-conductive matrix. The conductive composite shield has a resistivity of less than 0.05 ohm·cm. The processes of producing cable shielding assembles include positioning the conductive composite shield. The positioning is at least partially around a conductor, at least partially around a dielectric material, at least partially surrounded by a jacket material, or a combination thereof.

### FIELD OF THE INVENTION

The present invention is directed to cable shielding assemblies and processes of producing such assemblies. More particularly, the present invention is directed to cable shielding assemblies with conductive composite shields.

### BACKGROUND OF THE INVENTION

In general, cable shielding materials can be metallic or include ferrites. Metallic shields come in the form of braids, tapes, tubular, spiral, knitted wire mesh with a plastic cover, laminates, plated yarns and fabrics, and many more arrangements. Such shields provide shielding effect for low frequency applications, but they have several drawbacks. For example, braids have diminishing shielding effectiveness in high frequency ranges due to poor optical coverage. Metallic shields can be heavy and/or require costly and complex plating processes, as well as, braiding and/or tape-wrapping processes. Ferrite beads are used for high frequency noise suppression, but they can be limited by the frequency range that the specific type of ferrite allows and are not suitable for high frequency signal devices.

A cable shielding assembly and process of producing a cable shielding assembly that show one or more improvements in comparison to the prior art would be desirable in the art.

### BRIEF DESCRIPTION OF THE INVENTION

In an embodiment, a cable shielding assembly includes a conductor and a conductive composite shield extending around at least a portion of the conductor, the conductive composite shield having a non-conductive matrix and conductive particles within the non-conductive matrix. The conductive composite shield has a resistivity of less than 0.05 ohm·cm.

In another embodiment, a cable shielding assembly includes a conductor, a dielectric material extending around at least a portion of the conductor, a conductive composite shield extending around at least a portion of the conductor and at least a portion of the dielectric material, the conductive composite shield having a non-conductive matrix and conductive particles within the non-conductive matrix, and a jacket material extending around at least a portion of the conductive composite shield. The conductive composite shield has a resistivity of less than 0.05 ohm·cm.

In another embodiment, a process of producing a cable shielding assembly includes positioning a conductive composite shield, the conductive composite shield having a non-conductive matrix and conductive particles within the non-conductive matrix. The positioning is at least partially around a conductor, at least partially around a dielectric material, at least partially surrounded by a jacket material, or a combination thereof. The conductive composite shield has a resistivity of less than 0.05 ohm·cm.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic view of an embodiment of a cable shielding assembly, according to the disclosure.

FIG. 2 is a graphical representation of shielding effectiveness in dB shown on the y-axis from 10 MHz to 67 GHz and frequency in GHz shown on the x-axis of an embodiment of a cable shielding assembly in comparison to shielding provided from braids and metal tape, according to the disclosure.

FIG. 3 is a graphical representation of shielding effectiveness in dB shown on the y-axis from 10 MHZ to 10 GHz and frequency in GHz shown on the x-axis of the embodiment of a cable shielding assembly as shown in FIG. 2, in comparison to shielding provided from braids and metal tape, according to the disclosure.

FIG. 4 is a graphical representation of tensile strength on the y-axis in MPa versus elongation of polymer bases of non-conductive matrices for cable shielding assemblies on the x-axis in percent, according to embodiments of the disclosure.

Wherever possible, the same reference numbers will be used throughout the drawings to represent the same parts.

### DETAILED DESCRIPTION OF THE INVENTION

Provided are a cable shielding assembly and process of producing the cable shielding assembly. Embodiments of the present disclosure, for example, in comparison to concepts failing to include one or more of the features disclosed herein, permit increases in shielding of electronic components, permit increased shielding effectiveness in higher frequency ranges, permit flexibility, permit decreased fabrication costs, permit reduction of weight of articles including such shields instead of alternative shielding mechanisms, permit heat-recoverable materials to be secured without an adhesive adversely increasing resistivity, provide shielding from electromagnetic interference, permit termination and grounding without the use of metal braids, permit other suitable advantages and distinctions, and permit combinations thereof.

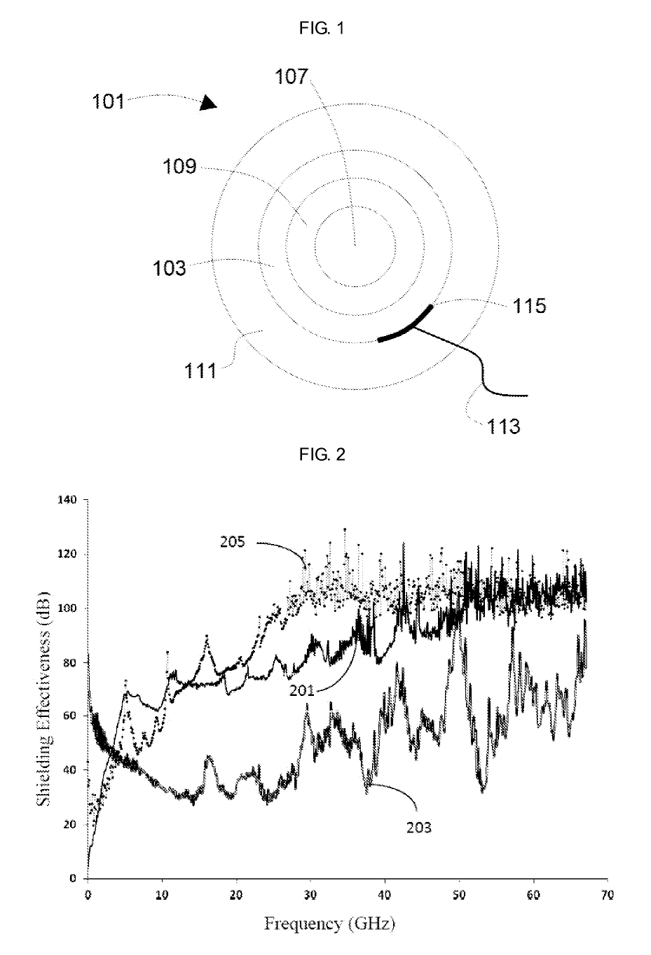

FIG. 1 shows a cable shielding assembly 101 including a conductor 107 and a conductive composite shield 103 extending around at least a portion of the conductor 107. The conductive composite shield 103 has a non-conductive matrix and conductive particles within the non-conductive matrix, for example, being an extrudable thermoplastic blend having a density range (for example, between 3 g/cc and 5 g/cc), a resistivity range (for example, less than 0.05 ohm·cm, less than 0.03 ohm·cm, less than 0.025 ohm·cm, or lower), and/or a contact resistance range (for example, 500 milliohm or lower). As used herein, the term “resistivity” refers to measurable values determined upon extrusion and/or full recovery and does not refer to values measured while in an expanded state. In one embodiment, the cable shielding assembly 101 forms a portion or entirety of an article, such as, a wire, a cable, or a combination thereof. As used herein, the term “shielding” is intended to reference an independent structure or portion of an independent structure. It is not intended to encompass coatings or such layers positioned on another structure. Suitable resistivity values of the conductive composite shield 103 include are less than 0.025 ohm·cm, for example, between 0.025 ohm·cm and 0.008 ohm·cm.

The thickness of the conductive composite shield 103 is between 0.4 mm and 2 mm, 0.4 mm and 1.6 mm, 0.5 mm, 1 mm, 1.5 mm, between 0.07 mm and 0.5 mm, between 0.1 mm and 0.5 mm, between 0.2 mm and 0.5 mm, greater than 0.1 mm, greater than 0.2 mm, greater than 0.4 mm, or any suitable combination, sub-combination, range, or sub-range therein.

In one embodiment, the cable shielding assembly 101 includes a dielectric material 109 being at least partially surrounded by the conductive composite shield 103, a jacket material 111 at least partially surrounding the conductive composite shield 103, or a combination thereof.

In a further embodiment, the dielectric material 109 is devoid or substantially devoid of the conductive particles and includes the same polymer matrix material as the conductive composite shield 103 or another suitable species of the polymer matrix materials.

The cable shielding assembly 101 is capable of including other suitable features for termination and/or grounding. For example, in one embodiment, the direct solderability of the conductive composite shield 103 in the cable shielding assembly 101 permits the cable shielding assembly 101 to include one or more drain wires 113 or metal straps connected to the conductive composite shield 103. For example, in one embodiment, the drain wire(s) 113 or metal straps is/are electrically terminated/connected to the conductive composite shield 103 by solder 115 and are embedded within. Additionally or alternatively, termination and grounding of the cable shielding assembly 101 is capable of being achieved by a crimp coaxial connector.

In one embodiment, the material of the non-conductive matrix is selected based upon tensile strength and/or elongation at break (for example, based upon ASTM D638, Standard Test Method for Tensile Properties of Plastics). A polymer base of the non-conductive matrix impacts the tensile strength at break and elongation at break.

For example, in one embodiment, the PVDF is in the non-conductive matrix as a polymer base, and the tensile strength at break of the non-conductive matrix is between 10 MPa and 20 MPa (for example, between 12 MPa and 15 MPa as shown in PVDF plots 402 of FIG. 4 and/or the elongation at break is between 100% and 200% (for example, between 130% and 160% as shown in FIG. 4).

In one embodiment, tetrafluoroethylene, hexafluoropropylene and vinylidene fluoride (THV) is in the non-conductive matrix as a polymer base, and the tensile strength at break of the non-conductive matrix is between 4 MPa and 8 MPa (for example, between 6 MPa and 7 MPa as shown in THV plots 404 of FIG. 4) and/or the tensile elongation at break is between 300% and 400% (for example, between 320% and 350% as shown in FIG. 4).

In one embodiment, metallocene-catalyzed polyethylene (m-LLDPE) is in the non-conductive matrix as a polymer base, and the tensile strength at break of the non-conductive matrix is between 4 MPa and 10 MPa (for example, between 6 MPa and 8 MPa as shown in m-LLDPE plots 406 of FIG. 4) and/or the tensile elongation at break is between 400% and 600% (for example, between 450% and 500% as shown in FIG. 4).

Suitable non-conductive matrices include, but are not limited to, the PVDF, copolymers of vinylidene fluoride (VDF) and hexafluoropropylene (HFP), terpolymers of VDF, HFP and tetrafluoroethylene (TFE), fluorinated ethylene propylene, ethylene tetrafluoroethylene, polytetrafluoroethylene, other suitable fluorinated matrices compatible with the conductive particles, or a combination thereof. Other suitable non-conductive matrices include, but are not limited to the polyethylene, polypropylene, ethylene-vinyl acetate, polyamide, neoprene, or a combination thereof.

In one embodiment, the non-conductive matrix has a crystallinity within a specific range, for example, between 15% and 65%, between 15% and 35%, between 15% and 20%, between 18% and 19%, between 30% and 35%, between 32% and 34%, or any suitable combination, sub-combination, range, or sub-range therein.

The conductive particles are or include copper particles, tin particles, nickel particles, aluminum particles, carbon particles, carbon black, carbon nanotubes, graphene, silver-coated particles, nickel-coated particles, other suitable conductive particles compatible with the non-conductive matrix, or a combination thereof. Suitable morphologies for the conductive particles include, but are not limited to, dendrites, flakes, fibers, and spheres. In one embodiment, the conductive particles are or include copper dendrites having average sizes of between 20 micrometers and 30 micrometers, at a relative volume concentration of between 40% and 70% (for example, 60%), and tin spheres having average sizes of between 8 micrometers and 16 micrometers, at a relative volume concentration of between 30% and 50% (for example, 40%).

In one embodiment, the concentration of the conductive particles within the non-conductive matrix is above the percolation threshold, which is lower for semicrystalline polymers than amorphous polymers due to the semicrystalline polymers including more efficient filler network formation around polymer crystallites. Additionally or alternatively, in one embodiment, the concentration of the conductive particles within the non-conductive matrix is below a recrystallization-limiting threshold. As used herein, the phrase “recrystallization-limiting threshold” refers to a concentration of the conductive particles within in the non-conductive matrix at which the cooling after melt-mixing would not permit a substantially equivalent reformation of crystals in the non-conductive matrix.

Suitable volume concentrations of the conductive particles within the non-conductive matrix include between 20% and 40% total loading, between 20% and 35% total loading, between 25% and 40% total loading, between 25% and 35% total loading, between 28% and 32% total loading, between 29% and 31% total loading, or any suitable combination, sub-combination, range, or sub-range therein.

In addition to the non-conductive matrix and the conductive particles, the conductive composite shield 103 includes any other suitable constituents. For example, in one embodiment, the conductive composite shield 103 includes a sebacate-type of plasticizer. Suitable concentrations of the sebacate-type plasticizer include, but are not limited to, a volume concentration of between 5% and 10% (for example, 7.5%). In one embodiment, the composite shield 103 includes a process aid for facilitating filler dispersion and increasing processability in a homogenous or substantially homogenous manner. Additionally or alternatively, in other embodiments, the conductive composite shield 103 includes or is devoid of a crosslinking agent or crosslinking agents, antioxidant(s), flame retardant(s), coupling agent(s), or other additives.

The conductor 107, the conductive composite shield 103, the dielectric material 109, the jacket material 111, the drain wire(s) 113, the solder 115, and/or any other portion of the cable shielding assembly 101 is capable of being produced and/or applied by co-extrusion, tandem-extrusion, add-on processes, or a combination thereof.

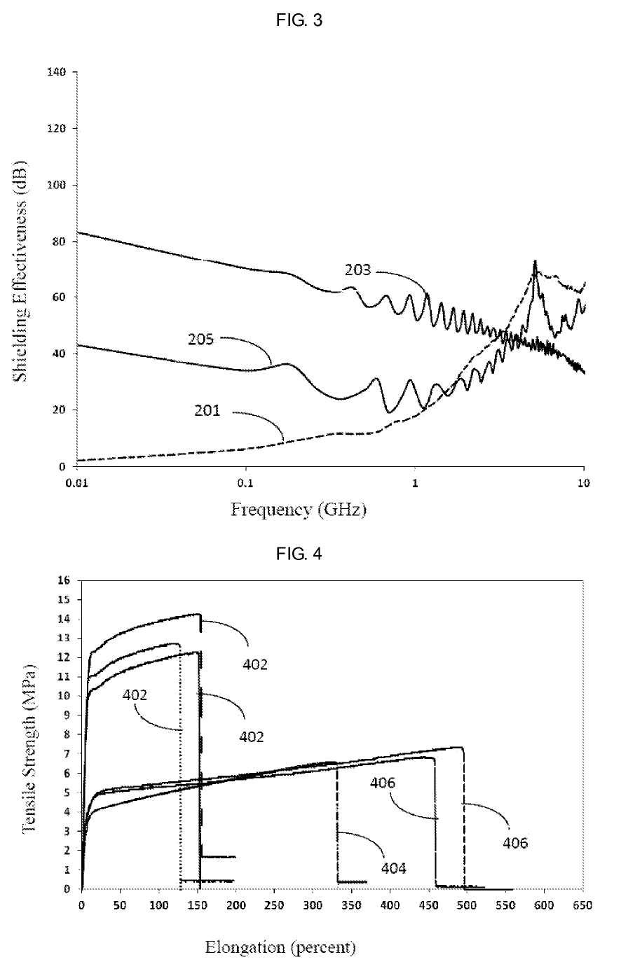

Referring to FIGS. 2 and 3, in one embodiment, shielding effectiveness of the conductive composite shield 103 (see 201) exceeds shielding effectiveness of double shields of braids and metal tape (see 203) within a frequency range of at least throughout, 5 GHz to 67 GHz, 5 GHz to 30 GHz, 40 GHz to 67 Hz, or any suitable combination, sub-combination, range, or sub-range therein as shown in FIGS. 2 and 3. In a further embodiment, shielding effectiveness of the conductive composite shield 103 (see 201) overlaps shielding effectiveness of the double shields of the braids and the metal tape when used with the conductive composite (see 205) within a frequency range of at least throughout 5 GHz to 7 GHz, 5 GHz to 12 GHz, 42 GHz to 67 GHz, or any suitable combination, sub-combination, range, or sub-range therein as shown in FIGS. 2 and 3. Specifically, the double shields of the braids and the metal tape compared to herein are silver-plated copper braids with silver-plated copper tape, for example, as used in the production of coaxial cable and having dimensions of 3.58 millimeter thickness and 3.25 millimeter thickness, respectively.

Unlike a homogeneous metal shield, the DC resistivity of the conductive composite shield does not completely predict the shielding effectiveness of the material. These conductive composite materials typically have much greater shielding effectiveness than would be expected, especially at frequencies greater than 1 GHz. Thus, a resistivity as high as 0.05 ohm-cm compared to metals in the 1×10⁻⁶ ohm cm range, can still give adequate shielding performance. In addition, using the conductive composite shield plus a metal braided or wrapped shield is synergistic. The metal shield has good low frequency shielding (i.e. in the KHz to 1 GHz range), but shielding effectives decreases at higher frequencies. The conductive composite shields described herein tend to have the opposite behavior. In addition, combining a metal braid with a conductive composite shield allows the use of conventional connectors and termination methods.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A cable shielding assembly, comprising:
a conductor; and
a conductive composite shield extending around at least a portion of the conductor, the conductive composite shield having a non-conductive matrix and conductive particles within the non-conductive matrix;
wherein the conductive composite shield has a resistivity of less than 0.05 ohm·cm.

2. The cable shielding assembly of claim 1, further comprising a dielectric material extending around at least a portion of the conductor, wherein the conductive composite shield extends around at least a portion of the dielectric material.

3. The cable shielding assembly of claim 1, further comprising a jacket material extending around at least a portion of the conductive composite shield.

4. The cable shielding assembly of claim 3, wherein the jacket material and the conductive composite shield are at least partially co-extruded.

5. The cable shielding assembly of claim 3, further comprising a drain wire embedded and electrically terminated between the conductive composite shield and the jacket material and extending from the cable shielding assembly.

6. The cable shielding assembly of claim 1, wherein the conductive composite shield has a resistivity of between 0.008 ohm·cm and 0.025 ohm·cm.

7. The cable shielding assembly of claim 1, wherein the conductive composite shield has a thickness of between 0.4 mm and 2 mm.

8. The cable shielding assembly of claim 1, wherein the conductive composite shield has a thickness of between 0.1 mm and 0.46 mm.

9. The cable shielding assembly of claim 1, wherein the shielding effectiveness of the conductive composite shield exceeds shielding effectiveness of double shields of braids and metal tape within a frequency range of at least throughout 5 GHz to 67 GHz, the braids being silver-plated copper braids having a 3.58 millimeter thickness and the metal tape being silver-plated copper tape having a 3.25 millimeter thickness.

10. The cable shielding assembly of claim 1, wherein the shielding effectiveness of the conductive composite shield exceeds shielding effectiveness of double shields of braids and metal tape within a frequency range of at least throughout 5 GHz to 30 GHz, the braids being silver-plated copper braids having a 3.58 millimeter thickness and the metal tape being silver-plated copper tape having a 3.25 millimeter thickness.

11. The cable shielding assembly of claim 1, wherein the shielding effectiveness of the conductive composite shield exceeds shielding effectiveness of double shields of braids and metal tape within a frequency range of at least throughout 40 GHz to 67 GHz, the braids being silver-plated copper braids having a 3.58 millimeter thickness and the metal tape being silver-plated copper tape having a 3.25 millimeter thickness.

12. The cable shielding assembly of claim 1, wherein the shielding effectiveness of the conductive composite shield overlaps shielding effectiveness of double shields of braids and metal tape within a frequency range of at least throughout 5 GHz to 7 GHz, the braids being silver-plated copper braids having a 3.58 millimeter thickness and the metal tape being silver-plated copper tape having a 3.25 millimeter thickness.

13. The cable shielding assembly of claim 1, wherein the shielding effectiveness of the conductive composite shield overlaps shielding effectiveness of double shields of braids and metal tape within a frequency range of at least throughout 5 GHz to 12 GHz, the braids being silver-plated copper braids having a 3.58 millimeter thickness and the metal tape being silver-plated copper tape having a 3.25 millimeter thickness.

14. The cable shielding assembly of claim 1, wherein the shielding effectiveness of the conductive composite shield overlaps shielding effectiveness of double shields of braids and metal tape within a frequency range of at least throughout 42 GHz to 67 GHz, the braids being silver-plated copper braids having a 3.58 millimeter thickness and the metal tape being silver-plated copper tape having a 3.25 millimeter thickness.

15. The cable shielding assembly of claim 1, wherein the non-conductive matrix includes material selected from the group consisting of polyvinylidene fluoride (PVDF), copolymers of vinylidene fluoride (VDF) and hexafluoropropylene (HFP), terpolymers of VDF, HFP and tetrafluoroethylene (TFE), fluorinated ethylene propylene, ethylene tetrafluoroethylene, polytetrafluoroethylene, a fluorinated matrix compatible with the conductive particles, and combinations thereof.

16. The cable shielding assembly of claim 1, wherein the non-conductive matrix includes material selected from the group consisting of polyethylene, polypropylene, ethylene-vinyl acetate, polyamide, neoprene, and combinations thereof.

17. The cable shielding assembly of claim 1, wherein the conductive particles include particles selected from the group consisting of copper particles, tin particles, nickel particles, aluminum particles, carbon particles, carbon black, carbon nanotubes, graphene, silver-coated particles, nickel-coated particles, or a combination thereof.

18. The cable shielding assembly of claim 1, wherein the conductive particles include carbon black, carbon nanotubes, graphene, or a combination thereof.

19. A cable shielding assembly, comprising:
a conductor;
a dielectric material extending around at least a portion of the conductor;
a conductive composite shield extending around at least a portion of the conductor and at least a portion of the dielectric material, the conductive composite shield having a non-conductive matrix and conductive particles within the non-conductive matrix;
a jacket material extending around at least a portion of the conductive composite shield;
wherein the conductive composite shield has a resistivity of less than 0.05 ohm·cm.

20. A process of producing a cable shielding assembly, the process comprising:
positioning a conductive composite shield, the conductive composite shield having a non-conductive matrix and conductive particles within the non-conductive matrix;
wherein the positioning is at least partially around a conductor, at least partially around a dielectric material, at least partially surrounded by a jacket material, or a combination thereof;
wherein the conductive composite shield has a resistivity of less than 0.05 ohm·cm.
